(19) United States
(12) Patent Application Publication
(10) Pub. No.: US 2025/0212539 A1
(43) Pub. Date: Jun. 26, 2025

(54) IMAGE SENSING DEVICE

(71) Applicant: SK hynix Inc., Icheon-si (KR)

(72) Inventor: Dong Ha KIM, Icheon-si (KR)

(21) Appl. No.: 18/658,096

(22) Filed: May 8, 2024

(30) Foreign Application Priority Data
Dec. 21, 2023 (KR) 10-2023-0188352

(51) Int. Cl. H01L 27/146

(52) U.S. Cl. CPC H10F 39/8053; H10F 39/807; H10F 39/8063

(57) ABSTRACT

The present disclosure relates to an image sensing device including a pixel array including a plurality of unit pixels is arranged. Each of the plurality of unit pixels includes: a substrate; a planarization layer formed over the substrate; and a color filter disposed over the planarization layer. The color filter includes at least one of a white color filter, a green color filter, a blue color filter, or a red color filter. The planarization layer includes a material of the white color filter.

### CROSS-REFERENCE TO RELATED APPLICATION(S)

This patent document claims the priority and benefits of Korean Patent Application No. 10-2023-0188352, filed on Dec. 21, 2023, which is incorporated by reference in its entirety as part of the disclosure of this patent document.

### TECHNICAL FIELD

Various embodiments of the disclosed technology relate to an image sensing device.

### BACKGROUND

An image sensing device refers to a semiconductor device that captures and converts an optical image to electrical signals. With the development of automobile, medical, computer and telecommunication industries, the demand for high-performance image sensing devices is increasing in various devices such as smart phones, digital cameras, game devices, Internet of Things, robots, security cameras, and medical micro-cameras.

The most common types of image sensing devices are charge coupled device (CCD) image sensing devices and complementary metal oxide semiconductor (CMOS) image sensing devices.

### SUMMARY

The disclosed technology can be implemented in some embodiments to provide an image sensing device capable of improving a sensitivity of a visible light region and a quantum efficiency of an infrared region.

One embodiment is an image sensing device including a pixel array including a plurality of unit pixels is arranged. The pixel array is configured to detect incident light to the pixel array to generate pixel signals indicative of an image carried by the incident light. Each of the plurality of unit pixels includes: a substrate; a planarization layer formed over the substrate; and a color filter disposed over the planarization layer. The color filter includes at least one of a white color filter, a green color filter, a blue color filter, or a red color filter. The planarization layer includes a material of the white color filter. The substrate supports a photosensing element for the unit pixel and the color filter is configured to filter incident light to be detected by the unit pixel.

In some implementations, a device isolation region may be disposed between planarization layers of two adjacent unit pixels.

In some implementations, a trench region may be disposed below the planarization layer.

In some implementations, the trench region may have a shape having a width decreasing from a top surface of the substrate toward a bottom surface of the substrate.

The trench region may include a first trench, a second trench, a third trench, and a fourth trench that are disposed below the white color filter, the green color filter, the blue color filter, and the red color filter, respectively.

In some implementations, at least two of the first trench, the second trench, the third trench, and the fourth trench may have different depths from each other.

In another aspect, an image sensing device is provided to include a pixel array including unit pixels, the unit pixels include a first unit pixel including a white color filter, a second unit pixel including a green color filter, a third unit pixel including a blue color filter, and a fourth unit pixel including a red color filter; a planarization layer disposed in lower portions of the first unit pixel, the second unit pixel, the third unit pixel, and the fourth unit pixel. The planarization layer includes a same material as a material of the white color filter. The pixel array is configured to sense incident light to generate pixel signals indicative of an image in the incident light and the white color filter, the green color filter, the blue color filter, and the red color filter are configured to filter incident light by the first unit pixel, the second unit pixel, and the third unit pixel, and the fourth unit pixel, respectively.

In some implementations, the device isolation region may be disposed between planarization layers of two adjacent unit pixels.

In some implementations, the first unit pixel may include: a substrate; the planarization layer disposed on the substrate; the white color filter disposed on the planarization layer; a microlens disposed over the white color filter; and a first trench disposed below the planarization layer and within the substrate.

In some implementations, the second unit pixel may include: the substrate; the planarization layer disposed on the substrate; the green color filter disposed on the planarization layer; a microlens disposed over the green color filter; and a second trench disposed below the planarization layer and within the substrate.

In some implementations, the third unit pixel may include: the substrate; the planarization layer disposed on the substrate; the blue color filter disposed on the planarization layer; a microlens disposed over the blue color filter; and a third trench disposed below the planarization layer and within the substrate.

In some implementations, the fourth unit pixel may include: the substrate; the planarization layer disposed on the substrate; the red color filter disposed on the planarization layer; a microlens disposed over the red color filter; and a fourth trench disposed below the planarization layer and within the substrate.

In some implementations, each of the first trench, the second trench, the third trench, and the fourth trench may have a width that increases away from a top surface of the substrate.

In some implementations, at least two of the first trench, the second trench, the third trench, and the fourth trench may have different depths from each other.

In some implementations, a depth of the first trench may be greater than a depth of the second trench.

In some implementations, a depth of the first trench may be greater than a depth of the third trench.

In some implementations, a depth of the first trench may be greater than a depth of the fourth trench.

In some implementations, a depth of the second trench may be greater than a depth of the third trench.

In some implementations, a depth of the fourth trench may be greater than a depth of the second trench.

### BRIEF DESCRIPTION OF THE DRAWINGS

FIG. 1 is an example of a block diagram of an image sensing device based on some implementations of the disclosed technology.

FIG. 2 is an example of a view illustrating a pixel array based on some implementations of the disclosed technology.

FIG. 3 is an example of a cross-sectional view of a pixel array that is taken along line A-A′ in FIG. 2.

FIG. 4 is an example of a cross-sectional view of a pixel array that is taken along line B-B′ in FIG. 2.

FIG. 5 is an example of a view illustrating a trench region of a pixel array based on some implementations of the disclosed technology.

### DETAILED DESCRIPTION

Features, and certain advantages in connection with specific implementations of the disclosed technology disclosed in this patent document are described by example embodiments with reference to the accompanying drawings.

In the case of a security sensor, sensitivity is important in low illuminance even if the security sensor is degraded by crosstalk (Xtalk).

Some implementations of the disclosed technology suggest an imaging sensing device including a planarization layer, a white color filter, and a trench structure with different depths for each color. According to the suggested implementations, the sensitivity in a visible light region and quantum efficiency (QE) in an infrared (IR) region (850 nm) can be improved.

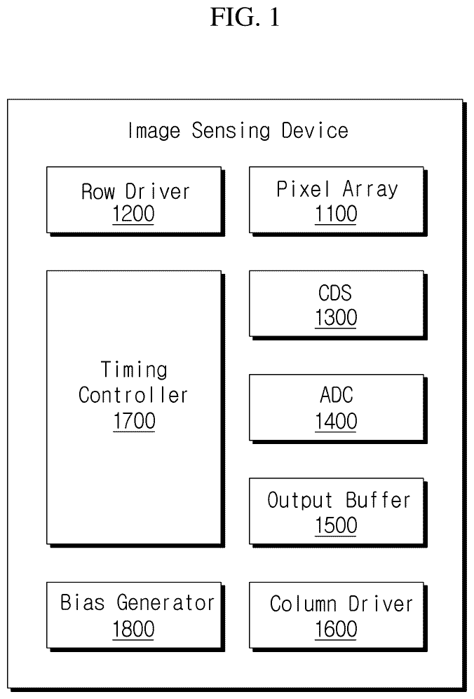

FIG. 1 is an example of a block diagram of an image sensing device based on some implementations of the disclosed technology.

Referring to FIG. 1, an image sensing device according to the embodiment may include a pixel array 1100, a row driver 1200, a correlated double sampler (CDS) 1300, and an analog-digital converter (ADC) 1400, an output buffer 1500, a column driver 1600, a timing controller 1700, and a bias generator 1800. Here, each of the components of the image sensing device is just an example, and at least some of the components may be added or omitted as needed.

The pixel array 1100 may include a plurality of pixels arranged in a plurality of rows and in a plurality of columns. In the embodiment, the plurality of pixels may be arranged in a two-dimensional pixel array including rows and columns. In another embodiment, a plurality of unit image pixels may be arranged in a three-dimensional pixel array. Each of the plurality of pixels may convert incident light or an optical signal received by the pixel into an electrical signal on a pixel basis. In some implementations, such conversion of light into an electrical signal may be carried out on a pixel group basis in which pixels within a pixel group (e.g., a group of neighboring or adjacent pixels may be used to collectively generate one pixel group signal based on individual pixel signals from the pixels in the group and such pixels in a group) may share at least a specific internal circuit. The pixel array 1100 may receive a drive signal including a row selection signal, a pixel reset signal, a transmission signal, etc., from the row driver 1200. The pixel of the pixel array 1100 may receive a row selection signal by the driving signal. The pixel of the pixel array 1100 may be activated, by the drive signal, to perform operations corresponding to the row selection signal, the pixel reset signal, and the transmission signal.

The row driver 1200 may activate the pixel array 1100 such that specific operations are performed on the pixels included in the row based on commands and control signals supplied by the timing controller 1700. In the embodiment, the row driver 1200 may select at least one pixel arranged in at least one row of the pixel array 1100. The row driver 1200 may generate the row selection signal in order to select at least one row among the plurality of rows. The row driver 1200 may sequentially enable the pixel reset signal and the transmission signal for pixels corresponding to at least one selected row. Accordingly, an analog reference signal and analog image signal generated from each pixel of the selected row may be sequentially transmitted to the correlated double sampler 1300. Here, the reference signal may be an electrical signal provided to the correlated double sampler 1300 when a sensing node of the pixel (e.g., floating diffusion node) is reset. The image signal may be an electrical signal provided to the correlated double sampler 1300 when photocharges generated by the pixel is accumulated in the sensing node. The reference signal representing pixel-specific reset noise and the image signal representing the intensity of incident light may be collectively referred to as pixel signals.

The image sensing device in FIG. 1 may be implemented as a complementary metal oxide semiconductor (CMOS) image sensor device for various applications. A CMOS image sensor samples the pixel signal twice in order to remove the difference between two samples, so that correlated double sampling can be used such that unwanted offset values of the pixel such as fixed pattern noise are removed. As an example, the correlated double sampling compares pixel output voltages obtained before and after the photocharges generated by the pixels in response to the received incident light are accumulated in the sensing node, thereby removing unwanted offset values and measuring the pixel output voltage based only on the incident light. In the embodiment, the correlated double sampler 1300 may sequentially sample and hold the reference signal and image signal provided to each of a plurality of column lines from the pixel array 1100. Thus, the correlated double sampler 1300 may sample and hold the levels of the reference signal and image signal corresponding to each column of the pixel array 1100.

The correlated double sampler 1300 may transmit the reference signal and image signal of each column as a correlated double sampling signal to the ADC 1400 based on the control signal from the timing controller 1700.

The ADC 1400 may convert the correlated double sampling signal for each column output from the correlated double sampler 1300 into a digital signal and output it. In the embodiment, the ADC 1400 may be implemented as a ramp-compare type ADC. The ramp-compare type ADC may include a comparison circuit and a counter. The comparison circuit compares a ramp signal that rises or falls over time and an analog pixel signal. The counter performs a counting operation until the ramp signal matches the analog pixel signal. In the embodiment, the ADC 1400 may convert the correlated double sampling signal generated by the correlated double sampler 1300 for each of the columns into a digital signal and output it.

The ADC 1400 may include a plurality of column counters corresponding to the columns of the pixel array 1100, respectively. The columns of the pixel array 1100 may be connected to the column counters, respectively, and image data may be generated by converting the correlated double sampling signal corresponding to each column into a digital signal by using the column counters. According to another embodiment, the ADC 1400 may include one global counter and may convert the correlated double sampling signal corresponding to each column into a digital signal by using a global code provided by the global counter.

The output buffer 1500 may temporarily hold and output image data in units of each column provided from the ADC 1400. The output buffer 1500 may temporarily store the image data output from the ADC 1400 based on the control signal of the timing controller 1700. The output buffer 1500 may operate as an interface that compensates for a difference in transmission (or processing) speed between the image sensing device and another device connected to the image sensing device.

The column driver 1600 may select a column of the output buffer 1500 based on the control signal of the timing controller 1700 and may control the image data temporarily stored in the selected column of the output buffer 1500 to be output sequentially. In the embodiment, the column driver 1600 may receive an address signal from the timing controller 1700, and the column driver 1600 may generate a column selection signal based on the address signal and may select the column of the output buffer 1500, thereby controlling the image data to be output from the selected column of the output buffer 1500 to the outside.

The timing controller 1700 may control at least one of the row driver 1200, the correlated double sampler 1300, the ADC 1400, the output buffer 1500, the column driver 1600, and the bias generator 1800.

The timing controller 1700 may provide a clock signal required for the operation of each component of the image sensing device, the control signal for timing control, the address signal for selecting rows or columns, and a signal for controlling the level of a bias voltage applied to the pixel array 1100, etc., to at least one of the row driver 1200, the correlated double sampler 1300, the ADC 1400, the output buffer 1500, the column driver 1600, and the bias generator 1800. According to the embodiment, the timing controller 1700 may include a logic control circuit, a phase lock loop (PLL) circuit, a timing control circuit, and a communication interface circuit, etc.

The bias generator 1800 may generate a bias voltage to suppress dark current which is generated in the pixel of the pixel array 1100 and may supply the bias voltage to the pixel array 1100.

The bias voltage may be determined during a wafer probe test of the image sensing device and may be stored in one-time programmable memory (OTP). For example, the bias voltage has a value capable of minimizing unnecessary power consumption without degrading the performance of the image sensing device and of maximizing an effect of suppressing the dark current. The value of the bias voltage can be experimentally determined.

The bias generator 1800 may generate a voltage corresponding to the bias voltage stored in the OTP memory. According to the embodiment, the OTP memory may be included in the image sensing device, and in particular may be included in the bias generator 1800.

According to the embodiment, the bias voltage may include a plurality of values.

For example, the plurality of values may correspond to a plurality of operation modes of the image sensing device, respectively. The dark currents generated at low and high illuminances may be different from each other, and the bias voltage supplied by the bias generator 1800 in order to effectively suppress the dark current in each environment may vary depending on the mode.

In some implementations, the plurality of values may correspond to a plurality of regions of the pixel array 1100, respectively. The dark currents generated according to the position of the pixel on the pixel array 1100 may be different from each other, and the bias voltage supplied by the bias generator 1800 in order to effectively suppress the dark current regardless of the position of the pixel may vary depending on the region.

In the example, the bias voltage may be a negative voltage with a negative sign. However, the bias voltage can have a different value, e.g., a positive voltage, without being limited to the negative voltage.

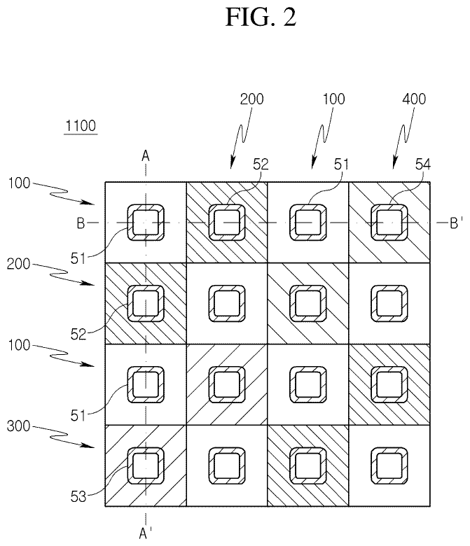

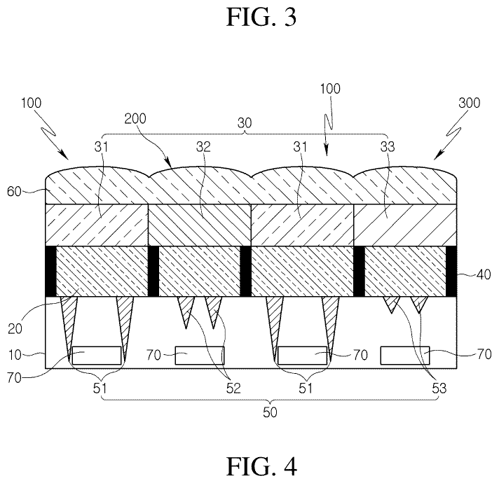

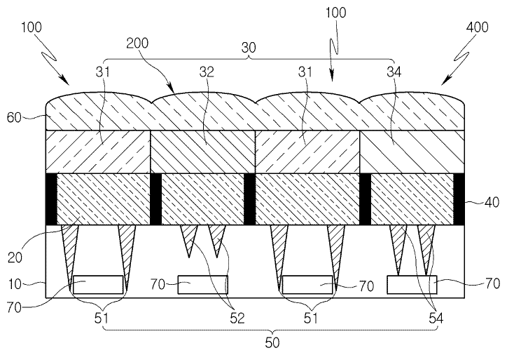

FIG. 2 is an example of a view illustrating a pixel array based on some implementations of the disclosed technology. FIG. 3 is an example of a cross-sectional view of the pixel array that is taken along line A-A′ in FIG. 2. FIG. 4 is an example of a cross-sectional view of the pixel array that is taken along line B-B′ in FIG. 2.

The pixel array of unit pixels is formed on or supported by a substrate. Each unit pixel may include a photosensing element or optical detector such as a photodiode for converting light into an electrical signal, a planarization layer, a color filter, a microlens, a device isolation region, and a trench region.

The pixel array according to the embodiment may include a plurality of unit pixels for capturing images carried by incident light using electrical unit pixel signals generated by conversion of light detected by the unit pixels, respectively. In some implementations, each of the unit pixels may include a substrate, a photosensing element or optical detector such as a photodiode for converting light into an electrical signal, a planarization layer, a color filter, a microlens, a device isolation region, and a trench region.

Referring to FIGS. 2-4, the pixel array according to the embodiment may include a first unit pixel 100 including a white color filter, a second unit pixel 200 including a green color filter, a third unit pixel 300 including a blue color filter, and a fourth unit pixel 400 including a red color filter.

The first unit pixel 100, the second unit pixel 200, the third unit pixel 300, and the fourth unit pixel 400 may include a substrate 10, a planarization layer 20, a color filter 30, a device isolation region 40, a trench region 50, and a microlens 60.

In some implementations, the substrate 10 may include a silicone (Si) material in a single crystal state.

In some implementations, the planarization layer 20 may be formed on or over the substrate 10. For example, the planarization layer 20 may be formed between the substrate 10 and the color filters 31, 32, 33, and 34. In some implementations, the planarization layer may be formed of or include the same material as that of the white color filter or an over coat (OC) material through a planarization process.

The material of the white color filter may be any oxide-based material or any photoresist-based material, which has no color.

The color filter 30 may be formed on or over the planarization layer 20. Since the color filter 30 is formed on the planarization layer 20, a focal point rises with the increase in optical height, thereby improving sensitivity.

In some implementations, the thickness of the color filter 30 may be less than that of the planarization layer 20. If the color filter 30 is formed after the planarization layer 20 is formed, the color filter 30 can be formed to be thin, and the sensitivity can be improved through this.

In some implementations, the color filter 30 may include at least one of a white color filter 31, a green color filter 32, a blue color filter 33, or a red color filter 34.

In some implementations, the device isolation region 40 may be formed between the planarization layers 20 to isolate the adjacent unit pixels from each other.

In some implementations, the device isolation region 40 may include at least one of a silicon oxynitride layer (SiON), a silicon oxide layer (SiO), or a silicon nitride layer (SiN).

In some implementations, the trench region 50 may be formed below the planarization layer 20 and formed within the substrate 10. For example, the trench region 50 may extend from the top surface of the substrate 10 to the bottom surface of the substrate 10. For example, the trench region 50 may be in direct contact with the planarization layer 20 at the top surface of the substrate 10.

The trench region 50 may serve to better focus incident light on the photoelectric conversion element, e.g., photodiode 70, through refraction or scattering.

In some implementations, the trench region 50 may be formed in a shape that becomes narrower from the top surface of the substrate 10 to the bottom surface of the substrate 10.

In some implementations, an upper width of the trench region 50 may be larger than a lower width of the trench region 50.

In some implementations, the trench region 50 may be formed below the planarization layer 20, e.g., the central portion of the planarization layer 20, of each of the unit pixels.

In some implementations, a depth of the trench region 50 may be formed differently in each of the unit pixels. The depth may refer to the length of each trench extending from the top surface of the substrate 10 toward the bottom surface of the substrate.

The trench region 50 may have different depths formed below the white color filter, the green color filter, the blue color filter, and the red color filter. The trench region 50 includes the first trench 51, the second trench 52, the third trench 53, and the fourth trench 54 that are disposed below the white color filter 31, the green color filter 32, the blue color filter 33, and the red color filter 34, respectively.

In some implementations, the trench region 50 may include at least one of an oxide layer, a nitride layer, or an oxynitride layer.

The microlens 60 is formed on or over the color filter 30 and serves to concentrate or focus light incident from the outside.

A photodiode 70 is formed in an inner region of the substrate 10, and an N-type impurity region and a P-type impurity region may be stacked in a vertical direction. The N-type impurity region and the P-type impurity region may be formed through an ion implantation process. The photodiode 70 is described as one example of the photoelectric conversion element which is configured to convert the incident light into electrical charges. In some implementation, in addition to a photodiode, the photoelectric conversion element can be as a phototransistor, a photogate, or a combination thereof, etc.

FIG. 3 is an example of a cross-sectional view of a pixel array that is taken along line A-A′ in FIG. 2. The pixel array as shown in FIG. 3 includes the first unit pixel 100 including the white color filter 31, the second unit pixel 200 including the green color filter 32, the first unit pixel 100 including the white color filter 31, and the third unit pixel 300 including the blue color filter 33, which are arranged along the line. Referring to FIG. 3, the first unit pixel 100 may include the substrate 10, the planarization layer 20, the white color filter 31, the microlens 60, and a first trench 51.

The white color filter 31 may be formed on or over the planarization layer 20 and may include an oxide-based material or a photoresist-based material, which has no color.

A microlens layer may be formed to include different microlenses 60 over different pixels to direct or focus incident light into respective pixels. In some implementations, the microlens 60 may be formed on or over the white color filter 31.

The first trench 51 may be formed below the planarization layer 20 and formed within the substrate 10.

In some implementations, the first trench 51 may be formed in a shape that becomes narrower from the top to the bottom, and may be formed below the planarization layer 20, e.g., the central portion of the planarization layer 20, of the first unit pixel 100.

Through the white color filter 31, sensitivity in a visible light region and a quantum efficiency (QE) in an infrared (IR) region (850 nm) can be improved. A sensitivity of an RGB pixel increases due to a low refractive index of the white color filter 31, and the quantum efficiency (QE) in the infrared (IR) region (850 nm) can be improved by white light scattered in the first trench 51.

The second unit pixel 200 may include the substrate 10, the planarization layer 20, a green color filter 32, the microlens 60, and a second trench 52.

The green color filter 32 may be formed on or over the planarization layer 20.

The microlens 60 may be formed on or over the green color filter 32.

The second trench 52 may be formed below the planarization layer 20 and formed within the substrate 10.

According to the embodiment, the second trench 52 may be formed in a shape that becomes narrower from the top to the bottom, and may be formed below the planarization layer 20, e.g., the central portion of the planarization layer 20, of the second unit pixel 200.

The third unit pixel 300 may include the substrate 10, the planarization layer 20, a blue color filter 33, the microlens 60, and a third trench 53.

The blue color filter 33 may be formed on or over the planarization layer 20.

The microlens 60 may be formed on or over the blue color filter 33.

The third trench 53 may be formed below the planarization layer 20 and formed within the substrate 10.

According to the embodiment, the third trench 53 may be formed in a shape that becomes narrower from the top to the bottom, and may be formed below the planarization layer 20, e.g., the central portion of the planarization layer 20, of the third unit pixel 300.

FIG. 4 is an example of a cross-sectional view of a pixel array that is taken along line B-B′ in FIG. 2. The pixel array as shown in FIG. 4 includes the first unit pixel 100 including the white color filter 31, the second unit pixel 200 including the green color filter 32, the first unit pixel 100 including the white color filter 31, and the fourth unit pixel 400 including the red color filter 34, which are arranged along the line. Referring to FIG. 4, the fourth unit pixel 400 may include the substrate 10, the planarization layer 20, the red color filter 34, the microlens 60, and a fourth trench 54.

The red color filter 34 may be formed on or over the planarization layer 20.

The microlens 60 may be formed on or over the red color filter 34.

The fourth trench 54 may be formed below the planarization layer 20 and formed within the substrate 10.

In some implementations, the fourth trench 54 may be formed in a shape that becomes narrower from the top to the bottom, and may be formed below the planarization layer 20, e.g., the central portion of the planarization layer 20, of the fourth unit pixel 400.

Referring to FIGS. 3 and 4, the first trench 51, the second trench 52, the third trench 53, and the fourth trench 54 are formed in the substrate 10. In the implementations, each trench has the shape narrowing from the top surface of the substrate 10 and the bottom surface of the substrate, and each trench has the upper width larger than the lower width.

In the examples, at least two of the first trench 51, the second trench 52, the third trench 53, and the fourth trench 54 may have different depths from each other.

In some implementations, the depth of the first trench 51 may be formed to be greater than the depth of the second trench 52.

In some implementations, the depth of the first trench 51 may be formed to be greater than the depth of the third trench 53.

In some implementations, the depth of the first trench 51 may be formed to be greater than the depth of the fourth trench 54.

In some implementations, the depth of the second trench 52 may be formed to be greater than the depth of the third trench 53.

In some implementations, the depth of the fourth trench 54 may be formed to be greater than the depth of the second trench 52.

In some implementations, the depth of the trench region is formed such that the first trench 51 of the first unit pixel 100 including the white color filter 31 has a depth greater than a depth of the fourth trench 54 of the fourth unit pixel 400 including the red color filter 34. In the implementation, the depth of the fourth trench 54 is greater than a depth of the second trench 52 of the second unit pixel 200 including the green color filter 32, and the depth of the second trench 52 is greater than a depth of the third trench 53 of the third unit pixel 300 including the blue color filter 33. With the first to fourth trenches 51-54 having the depths differently from one another, the sensitivity and quantum efficiency (QE) can be improved.

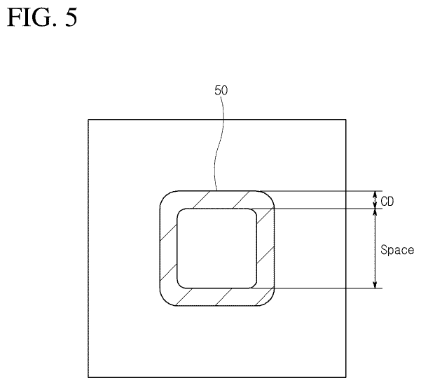

FIG. 5 is an example of a view illustrating a trench region of a pixel array based on some implementations of the disclosed technology.

Referring to FIG. 5, the trench region 50 may be formed below the central portion of the planarization layer 20 and may have a quadrangular structure. The trench region 50 as shown in FIG. 5 may be any one of the first trench 51, the second trench 52, the third trench 53, or the fourth trench 54.

Some implementations of the disclosed technology suggest an imaging sensing device including a structure in which a critical dimension (CD) and a trench spacing of the first trench 51 of the first unit pixel 100 including the white color filter 31 are larger than a critical dimension (CD) and a trench spacing of at least one of the second trench 52, the third trench 53, or the fourth trench 54. According to the suggested implementations, the quantum efficiency (QE) in the infrared (IR) region can be improved.

The sensitivity in a visible light region and the quantum efficiency (QE) in the infrared (IR) region (850 nm) can be improved by the first unit pixel 100 including the white color filter 31 and by the first trench 51, the second trench 52, the third trench 53, and the fourth trench 54, which have different depths from one another.

While various embodiments have been described above, variations and improvements of the disclosed embodiments and other embodiments may be made based on what is described or illustrated in this document.

I claim:

1. An image sensing device, comprising:
a pixel array including a plurality of unit pixels is arranged,
wherein each of the plurality of unit pixels comprises:
a substrate;
a planarization layer formed over the substrate; and
a color filter disposed over the planarization layer,
wherein the color filter comprises at least one of a white color filter, a green color filter, a blue color filter, or a red color filter, and
wherein the planarization layer comprises a material of the white color filter.

2. The image sensing device of claim 1, further comprising a device isolation region disposed between planarization layers of two adjacent unit pixels.

3. The image sensing device of claim 2, further comprising a trench region disposed below the planarization layer.

4. The image sensing device of claim 3, wherein the trench region has a shape having a width decreasing from a top surface of the substrate toward a bottom surface of the substrate.

5. The image sensing device of claim 3, wherein the trench region includes a first trench, a second trench, a third trench, and a fourth trench that are disposed below the white color filter, the green color filter, the blue color filter, and the red color filter, respectively.

6. The image sensing device of claim 5, wherein at least two of the first trench, the second trench, the third trench, and the fourth trench have different depths from each other.

7. An image sensing device, comprising:
a pixel array including unit pixels, the unit pixels include a first unit pixel including a white color filter, a second unit pixel including a green color filter, a third unit pixel including a blue color filter, and a fourth unit pixel including a red color filter;
a planarization layer disposed in lower portions of the first unit pixel, the second unit pixel, the third unit pixel, and the fourth unit pixel; and
wherein the planarization layer comprises a same material as a material of the white color filter.

8. The image sensing device of claim 7, further comprising a device isolation region disposed between planarization layers of two adjacent unit pixels.

9. The image sensing device of claim 8, wherein the first unit pixel comprises:
a substrate;
the planarization layer disposed on the substrate;
the white color filter disposed on the planarization layer;
a microlens disposed over the white color filter; and
a first trench disposed below the planarization layer and within the substrate.

10. The image sensing device of claim 9, wherein the second unit pixel comprises:
the substrate;
the planarization layer disposed on the substrate;
the green color filter disposed on the planarization layer;
a microlens disposed over the green color filter; and
a second trench disposed below the planarization layer and within the substrate.

11. The image sensing device of claim 10, wherein the third unit pixel comprises:
the substrate;
the planarization layer disposed on the substrate;
the blue color filter disposed on the planarization layer;
a microlens disposed over the blue color filter; and
a third trench disposed below the planarization layer and within the substrate.

12. The image sensing device of claim 11, wherein the fourth unit pixel comprises:
the substrate;
the planarization layer disposed on the substrate;
the red color filter disposed on the planarization layer;
a microlens disposed over the red color filter; and
a fourth trench disposed below the planarization layer and within the substrate.

13. The image sensing device of claim 12, wherein each of the first trench, the second trench, the third trench, and the fourth trench have a width that increases away from a top surface of the substrate.

14. The image sensing device of claim 12, wherein at least two of the first trench, the second trench, the third trench, and the fourth trench have different depths from each other.

15. The image sensing device of claim 14, wherein a depth of the first trench is greater than a depth of the second trench.

16. The image sensing device of claim 14, wherein a depth of the first trench is greater than a depth of the third trench.

17. The image sensing device of claim 14, wherein a depth of the first trench is greater than a depth of the fourth trench.

18. The image sensing device of claim 14, wherein a depth of the second trench is greater than a depth of the third trench.

19. The image sensing device of claim 14, wherein a depth of the fourth trench is greater than e depth of the second trench.
